(19) United States
(12) Patent Application Publication
(10) Pub. No.: US 2025/0158355 A1
(43) Pub. Date: May 15, 2025

(54) OPTICAL SEMICONDUCTOR DEVICE

(71) Applicant: Mitsubishi Electric Corporation, Tokyo (JP)

(72) Inventors: Ayumi FUCHIDA, Tokyo (JP); Tatsuki OTANI, Tokyo (JP); Kosuke SHINOHARA, Tokyo (JP)

(73) Assignee: Mitsubishi Electric Corporation, Tokyo (JP)

(21) Appl. No.: 18/838,438

(22) PCT Filed: May 26, 2022
(86) PCT No.: PCT/JP2022/021591

§ 371 Date: Aug. 14, 2024

(51) Int. Cl. H01S 5/024; H01S 5/0231

(52) U.S. Cl. CPC H01S 5/02469; H01S 5/0231

(57) ABSTRACT

An optical semiconductor device includes a stem including a first surface and a second surface on a side opposite to the first surface; a semiconductor laser provided on the first surface side of the stem; a lead pin configured to penetrate through the stem from the first surface to the second surface; and a heat dissipation block including a third surface and a fourth surface on a side opposite to the third surface, the third surface coming into contact with the second surface of the stem, wherein the heat dissipation block includes a groove notching a side surface connecting the third surface and the fourth surface and penetrating through the heat dissipation block from the third surface to the fourth surface, an insulation film is provided on an inside surface of the groove, and the lead pin is inserted into the groove of the heat dissipation block.

### FIELD

The present disclosure relates to an optical semiconductor device.

### BACKGROUND

PTL 1 discloses a laser package in which a laser is hermetically sealed in a package including a package base and a cap. The laser is fixed onto the package base. A plurality of lead pins including a lead pin for supplying a drive current to the laser are drawn out from the package base. A heat dissipation member higher in thermal conductivity than the package base is attached to a bottom surface of the package base. The heat dissipation member includes a single or a plurality of insertion holes into which the lead pins are inserted.

### CITATION LIST

### Patent Literature

[PTL 1] JP 2007-27413 A

### SUMMARY

### Technical Problem

Along with increase in output power and in operation speed of an optical element, a heat generation amount by a semiconductor laser chip, a driving IC chip, and a Peltier element for cooling the chips incorporated in the package is increased. When a temperature of the laser chip is increased with increase in heat generation amount, optical output may be reduced, a high-speed optical signal may be deteriorated, and the laser chip may fail.

As a countermeasure thereagainst, a configuration in which a heat dissipation block is brought into contact with a side surface of a stem and a side surface of a lens cap is conceivable. In such a configuration, however, a heat dissipation path easily becomes long as compared with a configuration in which the heat dissipation block is disposed on a rear surface of the stem. Further, it is difficult to increase a contact area between the heat dissipation block and the stem, and heat dissipation efficiency may be lowered. In a technique disclosed in PTL 1, a heat dissipation distance can be reduced by bringing the heat dissipation block into contact with the rear surface of the stem. However, a lead pin is inserted through an insertion hole provided in the heat dissipation block, which may limit an attachment method or an assembling order of the heat dissipation block. Further, in terms of a position and a dimension of the insertion hole, and formation of an insulator covering an inside of the insertion hole, high process accuracy may be required.

An object of the present disclosure is to provide an optical semiconductor device that can be easily manufactured.

### Solution to Problem

An optical semiconductor device according to the first disclosure includes a stem including a first surface and a second surface on a side opposite to the first surface; a semiconductor laser provided on the first surface side of the stem; a lead pin configured to penetrate through the stem from the first surface to the second surface; and a heat dissipation block including a third surface and a fourth surface on a side opposite to the third surface, the third surface coming into contact with the second surface of the stem, wherein the heat dissipation block includes a groove notching a side surface connecting the third surface and the fourth surface and penetrating through the heat dissipation block from the third surface to the fourth surface, an insulation film is provided on an inside surface of the heat dissipation block forming the groove, and the lead pin is inserted into the groove of the heat dissipation block.

An optical semiconductor device according to the second disclosure includes a stem including a first surface and a second surface on a side opposite to the first surface; a semiconductor laser provided on the first surface side of the stem; a plurality of lead pins configured to penetrate through the stem from the first surface to the second surface; and a heat dissipation block including a third surface and a fourth surface on a side opposite to the third surface, the third surface coming into contact with the second surface of the stem, wherein an insulation film is provided on a side surface of the heat dissipation block connecting the third surface and the fourth surface, and the heat dissipation block extends from a center part of the second surface of the stem through a space among the plurality of lead pins.

### Advantageous Effects of Invention

In the optical semiconductor device according to the first disclosure, the heat dissipation block includes the groove notching the side surface connecting the third surface and the fourth surface and penetrating through the heat dissipation block from the third surface to the fourth surface. The lead pin is inserted into the groove. Therefore, the heat dissipation block is easily attachable to the stem, and the optical semiconductor device can be easily manufactured.

In the optical semiconductor device according to the second disclosure, the heat dissipation block extends from the center part of the second surface of the stem through the space among the plurality of lead pins. Therefore, it is unnecessary to form insertion holes in the heat dissipation block, and the optical semiconductor device can be easily manufactured.

### BRIEF DESCRIPTION OF DRAWINGS

FIG. 1 is cross-sectional view of an optical semiconductor device according to Embodiment 1.

FIG. 2 is cross-sectional view of an optical semiconductor device according to Embodiment 1.

FIG. 3 is a cross-sectional view of an optical semiconductor device according to a first modification of Embodiment 1.

FIG. 4 is a cross-sectional view of an optical semiconductor device according to a second modification of Embodiment 1.

FIG. 5 is cross-sectional view of an optical semiconductor device according to Embodiment 2.

FIG. 6 is cross-sectional view of an optical semiconductor device according to Embodiment 2.

FIG. 7 is cross-sectional view of an optical semiconductor device according to Embodiment 3.

FIG. 8 is cross-sectional view of an optical semiconductor device according to Embodiment 3.

FIG. 9 is a cross-sectional view of an optical semiconductor device according to a modification of Embodiment 3.

FIG. 10 is a cross-sectional view of an optical semiconductor device according to Embodiment 4.

FIG. 11 is a perspective view of a heat dissipation block according to Embodiment 4.

FIG. 12 is a cross-sectional view of an optical semiconductor device according to Embodiment 5.

FIG. 13 is a perspective view of a heat dissipation block according to Embodiment 5.

### DESCRIPTION OF EMBODIMENTS

An optical semiconductor device according to each embodiment will be described with reference to drawings. Identical or corresponding constitutional elements are given the same reference numerals, and the repeated description of such constitutional elements may be omitted.

### Embodiment 1

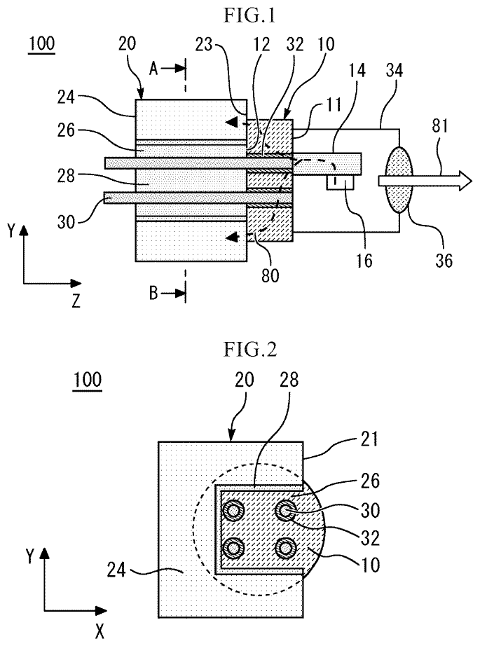

FIGS. 1 and 2 are cross-sectional views of an optical semiconductor device 100 according to Embodiment 1. In the following, a plane perpendicular to a light emission direction 81 of the optical semiconductor device 100 is referred to as an XY plane, and a direction parallel to the light emission direction 81 is referred to as a Z direction. The optical semiconductor device 100 includes a stem 10 including a first surface 11 and a second surface 12 on a side opposite to the first surface 11. A semiconductor laser 16 is provided on the first surface 11 side of the stem 10. FIG. 1 is a YZ cross-sectional view passing through a center of the stem 10. FIG. 2 is a diagram illustrating an XY cross-section taken along line A-B in FIG. 1 as viewed from the second surface 12 side of the stem 10.

A plurality of lead pins 30 penetrate through the stem 10 from the first surface 11 to the second surface 12. The stem 10 and the lead pins 30 are each made of a metal containing iron and the like. The stem 10 and the lead pins 30 each may have a gold-plated surface. The stem 10 has, for example, a disk shape having a diameter of about 5.6 mm and a thickness of about 1.2 mm. Each of the lead pins 30 has, for example, a diameter of 0.4 mm. A portion having a length of about 15 mm, of each of the lead pins 30 is drawn out from the second surface 12 side of the stem 10. A gap between the stem 10 and each of the lead pins 30 is filled with a sealing material 32 made of an insulation material such as glass. As a result, the stem 10 and each of the lead pins 30 are electrically insulated from each other. The plurality of lead pins 30 may include a lead pin 30 electrically short-circuited with the stem 10.

A mounting block 14 made of a metal material is mounted on the first surface 11 of the stem 10. The semiconductor laser 16 is mounted on the mounting block 14 so as to emit light in the Z direction. The semiconductor laser 16 is, for example, an end-face emission laser chip. The semiconductor laser 16 may be a surface emission laser or an LED as long as the semiconductor laser 16 is a light emitting element. The semiconductor laser 16 and each of the lead pins 30 are electrically connected using an unillustrated gold wire, an unillustrated wiring substrate, or the like. A current is injected from the lead pins 30, which makes it possible to operate the semiconductor laser 16.

A cylindrical lens barrel 34 made of a metal is welded to the first surface 11 of the stem 10. A glass lens 36 is attached to a front end of the lens barrel 34. The lens barrel 34 and the glass lens 36 cover and seal the mounting block 14 and the semiconductor laser 16.

A heat dissipation block 20 includes a third surface 23 and a fourth surface 24 on a side opposite to the third surface 23, and the third surface 23 comes into contact with the second surface 12 of the stem 10. In FIG. 2, a position of the stem 10 is illustrated by a broken line. The heat dissipation block 20 is made of a metal. The heat dissipation block 20 includes a groove 26 that notches a side surface 21 connecting the third surface 23 and the fourth surface 24 and penetrates through the heat dissipation block 20 from the third surface 23 to the fourth surface 24. The plurality of lead pins 30 are inserted into the groove 26. The groove 26 is formed such that the heat dissipation block 20 does not interfere with the lead pins 30. In the example illustrated in FIG. 2, the groove 26 of the heat dissipation block 20 has a rectangular shape, but may have a polygonal shape, a U-shape, or the like. A depth of the groove 26 from the side surface 21 is, for example, greater than or equal to an interval of the plurality of lead pins 30. A peripheral portion of the second surface 12 of the stem 10 is in contact with the third surface 23 of the heat dissipation block 20.

An insulation film 28 made of polyimide or the like is provided on an inside surface of the heat dissipation block 20 forming the groove 26. This makes it possible to prevent the lead pins 30 and the heat dissipation block 20 from electrically connected even when the lead pins 30 and the heat dissipation block 20 come into contact with each other.

Next, operation of the optical semiconductor device 100 is described. When the lead pins 30 are connected to a power supply and current injection is performed, the semiconductor laser 16 emits laser oscillation light. The laser oscillation light passes through the glass lens 36 and is emitted in the Z direction. At this time, the semiconductor laser 16 generates heat with laser oscillation. The heat is dissipated from the mounting block 14 high in thermal conductivity through the stem 10 as indicated by an arrow 80. At this time, by arranging the heat dissipation block 20 so as to come into contact with the second surface 12 of the stem 10, it is possible to dissipate the heat from the second surface 12 to the heat dissipation block 20 through a short heat dissipation path. As a result, it is possible to prevent the temperature of the semiconductor laser 16 from being excessively increased at injection of the current. This makes it possible to prevent deterioration of optical output characteristics and reliability.

The package is often generally assembled such that a light emission point of the semiconductor laser 16 as a heat generation source is positioned near a center of the stem 10. Therefore, when the heat dissipation block 20 comes into contact with the stem 10 at a region close to a center of the second surface 12 of the stem 10, the heat dissipation efficiency can be improved.

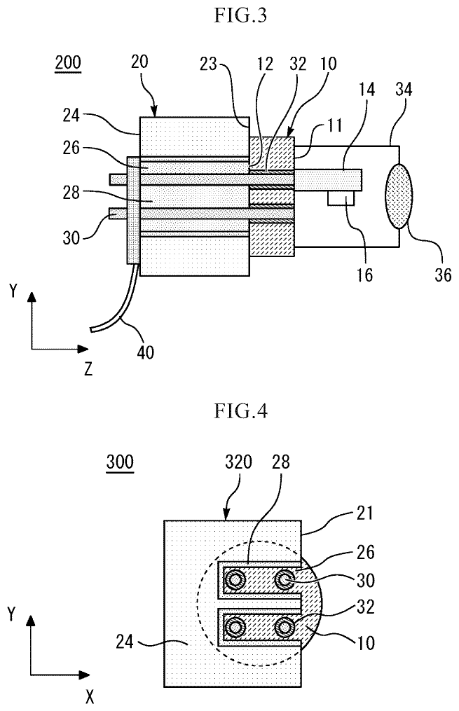

Next, effects by the optical semiconductor device 100 according to Embodiment 1 are described. FIG. 3 is a cross-sectional view of an optical semiconductor device 200 according to a first modification of Embodiment 1. In the optical semiconductor device 200, a flexible substrate 40 is connected to the lead pins 30 on the fourth surface 24 side of the heat dissipation block 20. The flexible substrate 40 includes a plurality of holes into which the lead pins 30 are inserted. The flexible substrate 40 further includes an electric wiring such as a wiring pattern. As a comparative example of the present embodiment, a structure in which insertion holes for the lead pins 30 are provided in a heat dissipation block is considered. In the comparative example, it is necessary to attach the heat dissipation block from the second surface 12 side of the stem 10 in the Z direction. Therefore, in the comparative example, it is necessary to attach the heat dissipation block before the flexible substrate 40 is attached to the lead pins 30.

In contrast, the heat dissipation block 20 according to Embodiment 1 can be attached to the stem 10 from two directions of the Z direction and the X direction. Therefore, in the present embodiment, the heat dissipation block 20 can be attached to the stem 10 after the flexible substrate 40 is attached to the lead pins 30. As described above, the present embodiment can enhance a degree of freedom of the attachment method or the assembling order of the heat dissipation block 20, and can improve flexibility of manufacturing processes.

Further, in the above-described comparative example, if dimensions or positions of the insertion holes of the heat dissipation block are varied, the lead pins 30 may be bent. Further, the heat dissipation block cannot be attached due to interference between the heat dissipation block and the lead pins 30. In addition, it is necessary to cover insides of the insertion holes each having a diameter of about several mm, with insulators. Accordingly, high process accuracy is required, and a processing cost of the heat dissipation block may be increased. In contrast, in the present embodiment, it is unnecessary to form the insertion holes in the heat dissipation block 20 and to form the insulators inside the insertion holes. Therefore, high process accuracy is not required, and a manufacturing cost can be suppressed.

In the present embodiment, since it is sufficient to insert the lead pins 30 into the groove 26, alignment between the heat dissipation block 20 and the lead pins 30 can be easily performed. This makes it possible to easily attach the heat dissipation block 20 to the stem 10. As a result, an assembling cost can be suppressed. As described above, in the present embodiment, the optical semiconductor device 100 can be easily manufactured. Further, the heat dissipation block 20 according to the present embodiment can be manufactured with less metal material than the heat dissipation bock including the insertion holes according to the comparative example. Therefore, a material cost can be suppressed.

FIG. 4 is a cross-sectional view of an optical semiconductor device 300 according to a second modification of Embodiment 1. The optical semiconductor device 300 is different in structure of a heat dissipation block 320 from the optical semiconductor device 100. The other configurations are similar to the configurations of the optical semiconductor device 100. The heat dissipation block 320 may include a plurality of grooves 26 corresponding to arrangement of the lead pins 30. In the optical semiconductor device 300, a contact area between the stem 10 and the heat dissipation block 320 can be increased as compared with the optical semiconductor device 100. Accordingly, the heat dissipation efficiency can be improved.

The shapes of the heat dissipation block 20 and the groove 26 according to the present embodiment are not limited to the shapes illustrated in FIG. 1 to FIG. 4. The heat dissipation block 20 may have an oblong shape, a polygonal shape, a circular shape, an elliptical shape, or other shapes as viewed from the Z direction. The groove 26 is not limited to a rectangular shape, and may have a polygonal shape, a U-shape, or other shapes. Further, the number of lead pins 30 is not limited.

These modifications can be applied, as appropriate, to optical semiconductor devices according to the following embodiments. Note that the optical semiconductor devices according to the following embodiments are similar to that of the first embodiment in many respects, and thus differences between the optical semiconductor devices according to the following embodiments and that of the first embodiment will be mainly described below.

### Embodiment 2

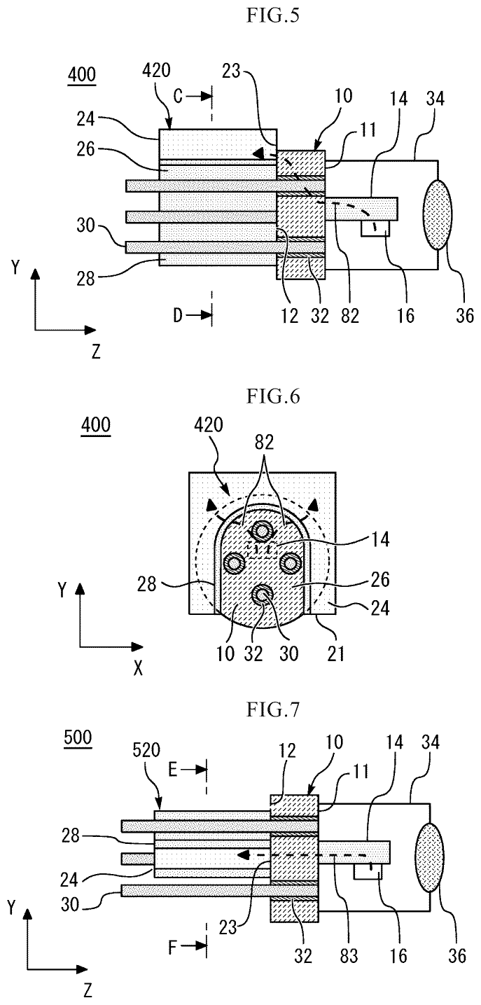

FIGS. 5 and 6 are cross-sectional views of an optical semiconductor device 400 according to Embodiment 2. FIG. 5 is a YZ cross-sectional view passing through the center of the stem 10. FIG. 6 is a diagram illustrating an XY cross-section taken along line C-D in FIG. 5 as viewed from the second surface 12 side of the stem 10. The optical semiconductor device 400 is different in structure of a heat dissipation block 420 from the optical semiconductor device 100. The other configurations are similar to the configurations of the optical semiconductor device 100. On the side surface 21 of the heat dissipation block 420, the groove 26 is provided so as to have a depth direction in the Y-direction. In other words, the groove 26 opens toward a Y-axis negative direction.

The semiconductor laser 16 is generally disposed so as to emit light from a center of the XY plane of the stem 10. Therefore, the mounting block 14 on which the semiconductor laser 16 is mounted is often disposed at a position deviated from the center of the stem 10. In the present embodiment, the mounting block 14 on which the semiconductor laser 16 is mounted is also provided at a position deviated to one side from the center of the stem 10, on the first surface 11 of the stem 10. The one side is a Y-axis positive direction in FIG. 5.

A bottom part of the groove 26 of the heat dissipation block 420 is provided on the one side, namely, on the Y-axis positive direction side. This makes it possible to reduce a distance between the bottom part of the groove 26 of the heat dissipation block 420 and the mounting block 14. In the present embodiment, a contact portion between the second surface 12 of the stem 10 and the heat dissipation block 420 is close to the mounting block 14. Therefore, as illustrated by an arrow 82, a heat dissipation path from the semiconductor laser 16 to the heat dissipation block 420 can be shortened. This makes it possible to improve heat dissipation efficiency.

### Embodiment 3

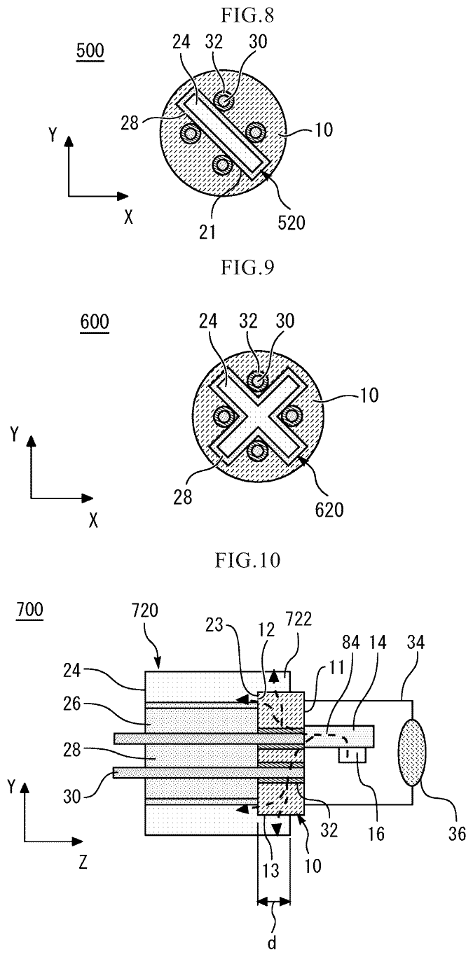

FIGS. 7 and 8 are cross-sectional views of an optical semiconductor device 500 according to Embodiment 3. The optical semiconductor device 500 is different in structure of a heat dissipation block 520 from the optical semiconductor device 100. The other configurations are similar to the configurations in Embodiment 1. FIG. 7 is a YZ cross-sectional view passing through the center of the stem 10. FIG. 8 is a diagram illustrating an XY cross-section taken along line E-F in FIG. 7 as viewed from the second surface 12 side of the stem 10.

As in Embodiment 1, the third surface 23 of the heat dissipation block 520 is in contact with the second surface 12 of the stem 10. The heat dissipation block 520 has, for example, a shape that can be disposed at a center part of the second surface 12 of the stem 10 among the plurality of lead pins 30. In other words, the heat dissipation block 520 extends from the center part of the second surface 12 of the stem 10 through a space among the plurality of lead pins 30. The heat dissipation block 520 has, for example, a rectangular-parallelepiped shape. In other words, the heat dissipation block 520 has an oblong shape as viewed from a direction perpendicular to the second surface 12.

The insulation film 28 made of polyimide or the like is provided on the side surface 21 of the heat dissipation block 520 connecting the third surface 23 and the fourth surface 24. The insulation film 28 is provided to prevent conduction between the lead pins 30 and the heat dissipation block 520. It is sufficient to provide the insulation film 28 on surfaces of the side surface 21 facing the lead pins 30.

In the present embodiment, effects similar to the effects in Embodiment 1 are also achievable. In other words, it is possible to easily manufacture the optical semiconductor device 100, and to suppress a material cost. Further, in the present embodiment, it is unnecessary to perform groove process on the heat dissipation block 520. Therefore, a process cost can be suppressed. In the present embodiment, the heat dissipation block 520 can be disposed at the center part of the stem 10. Therefore, as illustrated by an arrow 83, a heat dissipation path from the semiconductor laser 16 to the heat dissipation block 520 can be shortened. This makes it possible to efficiently dissipate heat.

It is sufficient for the heat dissipation block 520 to have a shape not interfering the lead pins 30, and the heat dissipation block 520 may have a columnar shape or a shape including irregularities. The heat dissipation block 520 may be disposed just below the mounting block 14. FIG. 9 is a cross-sectional view of an optical semiconductor device 600 according to a modification of Embodiment 3. The optical semiconductor device 600 includes a heat dissipation block 620. The heat dissipation block 620 has a cross shape as viewed from a direction perpendicular to the second surface 12. In a case of using the heat dissipation block 620, a contact area between the stem 10 and the heat dissipation block 620 can be increased as compared with the heat dissipation block 520. This makes it possible to improve heat dissipation efficiency. On the other hand, the heat dissipation block 620 can be attached to the stem 10 only from the Z direction. Therefore, as compared with Embodiment 1, a manufacturing process is limited.

As in Embodiment 1, the flexible substrate 40 may be connected to the plurality of lead pins 30 on the fourth surface 24 side of the heat dissipation block 520.

### Embodiment 4

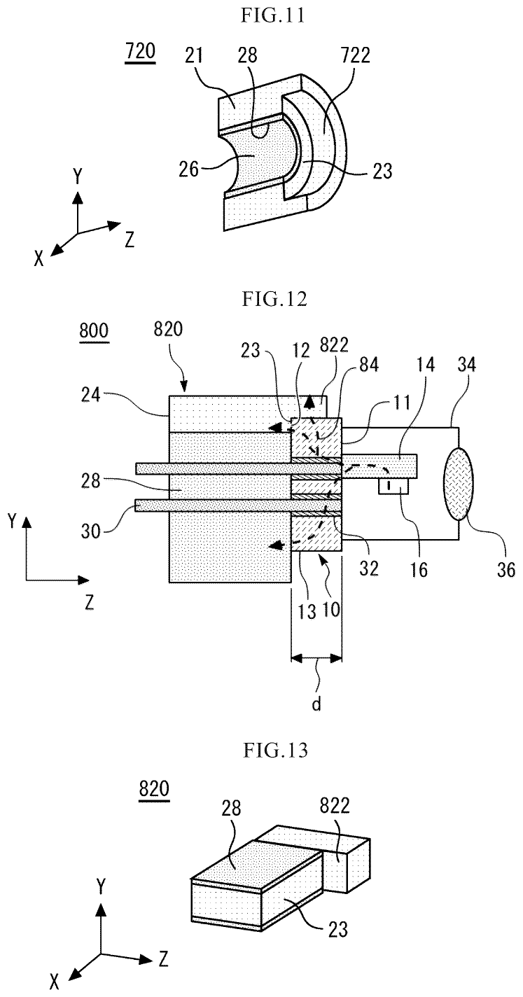

FIG. 10 is a cross-sectional view of an optical semiconductor device 700 according to Embodiment 4. FIG. 11 is a perspective view of a heat dissipation block 720 according to Embodiment 4. The optical semiconductor device 700 is different in structure of the heat dissipation block 720 from the optical semiconductor device 100. The other configurations are similar to the configurations in Embodiment 1. The heat dissipation block 720 has, for example, a semicircular shape as viewed from the Z direction. The heat dissipation block 720 includes the groove 26 into which the lead pins 30 are inserted, as with the heat dissipation block 20. The heat dissipation block 720 further includes a step part 722 that extends from the third surface 23 toward the stem 10 and comes into contact with a side surface 13 connecting the first surface 11 and the second surface 12 of the stem 10. The step part 722 has a height d from the third surface 23.

In the present embodiment, effects similar to the effects in Embodiment 1 are also achievable. Further, the heat dissipation block 720 comes into contact with the second surface 12 and the side surface 13 of the stem 10. Therefore, as illustrated by an arrow 84, a heat dissipation path from the side surface of the stem 10 to the heat dissipation block 720 is added. This makes it possible to efficiently dissipate heat. When the height d is greater than or equal to a thickness of the stem 10, a contact area between the step part 722 and the side surface 13 of the stem 10 is maximized, and heat dissipation property is also maximized. However, even when the height d is less than the thickness of the stem 10, certain heat dissipation property is obtainable. Further, the step part 722 also functions as an assembling guide. The step part 722 can determine positional relationship between the stem 10 and the heat dissipation block 720, and can suppress assembling deviation.

### Embodiment 5

FIG. 12 is a cross-sectional view of an optical semiconductor device 800 according to Embodiment 5. FIG. 13 is a perspective view of a heat dissipation block according to Embodiment 5. The optical semiconductor device 800 is different in structure of a heat dissipation block 820 from the optical semiconductor device 500. The other configurations are similar to the configurations in Embodiment 3. In the present embodiment, the step part according to Embodiment 4 is provided on the heat dissipation block according to Embodiment 3. The heat dissipation block 820 extends from the center part of the second surface 12 of the stem 10 through the space among the plurality of lead pins 30. The heat dissipation block 820 includes a step part 822 that extends from the third surface 23 toward the stem 10 and comes into contact with the side surface 13 of the stem 10.

The heat dissipation block 820 comes into contact with the second surface 12 and the side surface 13 of the stem 10. Therefore, in the present embodiment, it is possible to efficiently dissipate heat, as compared with Embodiment 3. In the present embodiment, the center part of the stem 10 close to the semiconductor laser 16 comes into contact with the heat dissipation block 820, as compared with Embodiment 4. Therefore, it is possible to efficiently dissipate heat from the second surface 12 of the stem 10. In contrast, in the present embodiment, the contact area between the side surface 13 of the stem 10 and the step part 822 is small as compared with Embodiment 4. Therefore, heat dissipation efficiency from the side surface 13 of the stem 10 is high in Embodiment 4. Further, in the present embodiment, the step part 822 can suppress assembling deviation, as in Embodiment 4.

Note that the technical features described in the above embodiments may be combined as appropriate.

### REFERENCE SIGNS LIST

10 stem, 11 first surface, 12 second surface, 13 side surface, 14 mounting block, 16 semiconductor laser, 20 heat dissipation block, 21 side surface, 23 third surface, 24 fourth surface, 26 groove, 28 insulation film, 30 lead pin, 32 sealing material, 34 lens barrel, 36 glass lens, 40 flexible substrate, 100 optical semiconductor device, 200 optical semiconductor device, 300 optical semiconductor device, 320 heat dissipation block, 400 optical semiconductor device, 420 heat dissipation block, 500 optical semiconductor device, 520 heat dissipation block, 600 optical semiconductor device, 620 heat dissipation block, 700 optical semiconductor device, 720 heat dissipation block, 722 step part, 800 optical semiconductor device, 820 heat dissipation block, 822 step part

1. An optical semiconductor device, comprising:
a stem including a first surface and a second surface on a side opposite to the first surface;
a semiconductor laser provided on the first surface side of the stem;
a lead pin configured to penetrate through the stem from the first surface to the second surface; and
a heat dissipation block including a third surface and a fourth surface on a side opposite to the third surface, the third surface coming into contact with the second surface of the stem, wherein
the heat dissipation block includes a groove notching a side surface connecting the third surface and the fourth surface and penetrating through the heat dissipation block from the third surface to the fourth surface,
an insulation film is provided on an inside surface of the heat dissipation block forming the groove, and
the lead pin is inserted into the groove of the heat dissipation block.

2. The optical semiconductor device according to claim 1, further comprising a mounting block provided at a position deviated to one side from a center of the stem on the first surface, the semiconductor laser being mounted on the mounting block, wherein
the groove has a bottom part provided on the one side.

3. The optical semiconductor device according to claim 1, wherein the heat dissipation block includes a plurality of the grooves.

4. The optical semiconductor device according to claim 1, wherein the heat dissipation block includes a step part extending from the third surface toward the stem and coming into contact with a side surface connecting the first surface and the second surface of the stem.

5. The optical semiconductor device according to claim 1, further comprising a flexible substrate connected to the lead pin on the fourth surface side of the heat dissipation block.

6. An optical semiconductor device, comprising:
a stem including a first surface and a second surface on a side opposite to the first surface;
a semiconductor laser provided on the first surface side of the stem;
a plurality of lead pins configured to penetrate through the stem from the first surface to the second surface; and
a heat dissipation block including a third surface and a fourth surface on a side opposite to the third surface, the third surface coming into contact with the second surface of the stem, wherein
an insulation film is provided on a side surface of the heat dissipation block connecting the third surface and the fourth surface, and
the heat dissipation block extends from a center part of the second surface of the stem through a space among the plurality of lead pins.

7. The optical semiconductor device according to claim 6, wherein the heat dissipation block has an oblong shape as viewed from a direction perpendicular to the second surface.

8. The optical semiconductor device according to claim 6, wherein the heat dissipation block has a cross shape as viewed from a direction perpendicular to the second surface.

9. The optical semiconductor device according to claim 6, wherein the heat dissipation block includes a step part extending from the third surface toward the stem and coming into contact with a side surface connecting the first surface and the second surface of the stem.

10. The optical semiconductor device according to claim 6, further comprising a flexible substrate connected to the plurality of lead pins on the fourth surface side of the heat dissipation block.
